(19) United States
(12) Patent Application Publication
(10) Pub. No.: US 2025/0040099 A1
(43) Pub. Date: Jan. 30, 2025

(54) LIQUID-TO-LIQUID RACK MOUNTED HEAT EXCHANGER

(71) Applicant: Quanta Computer Inc., Taoyuan City (TW)

(72) Inventors: Chao-Jung CHEN, Taoyuan City (TW); Yu-Nien HUANG, Taoyuan City (TW); Herman TAN, Taoyuan City (TW)

(21) Appl. No.: 18/481,130

(22) Filed: Oct. 4, 2023

Related U.S. Application Data
(60) Provisional application No. 63/515,774, filed on Jul. 26, 2023.

(51) Int. Cl. H05K 7/20

(52) U.S. Cl. CPC H05K 7/20627

(57) ABSTRACT

The present disclosure relates to a rack unit for circulating coolant to equipment racks. The rack unit has a cold coolant manifold for supplying coolant to an electronic component such as a server. The rack unit has a pump fluidly coupled to the cold coolant manifold for circulating the coolant. The rack unit has a hot coolant manifold for collecting hot coolant from the electronic component. The rack unit has a liquid-to-liquid heat exchanger fluidly coupled to the cold coolant manifold and the hot coolant manifold to form a first coolant loop. The first coolant loop transfers heat to a second coolant loop formed in part by the liquid-to-liquid heat exchanger.

### CROSS-REFERENCE TO RELATED APPLICATIONS

This application claims priority from and benefit of U.S. Provisional Patent Application Ser. No. 63/515,774, filed on Jul. 26, 2023, which is hereby incorporated by reference herein in its entirety.

### TECHNICAL FIELD

The present invention relates generally to immersion type liquid cooling systems, and more specifically, to a rack based liquid-to-liquid heat exchanger for supporting immersion cooled components.

### BACKGROUND

Electronic components, such as servers, include numerous electronic components that are powered by a common power supply. Servers generate an enormous amount of heat due to the operation of internal electronic devices such as controllers, processors, and memory. Overheating from the inefficient removal of such heat has the potential to shut down or impede the operation of such devices. Thus, current servers are designed to rely on air flow through the interior of the server to carry away heat generated from electronic components. Servers often include various heat sinks that are attached to the electronic components such as processing units. Heat sinks are constructed of metal to absorb the heat from the electronic components, thus transferring the heat away from the components. The heat from heat sinks must be vented away from the server through air flow. Air flow to vent away such heat is often generated by a fan system that is installed in the electronic component.

Due to the improvement of high-performance computing systems, the amount of heat that needs to be removed becomes higher with each new generation of computing systems. With the advent of more powerful components, traditional air cooling, in combination with fan systems, is inadequate to sufficiently remove heat generated by newer generation components. Thus, the development of liquid cooling has been spurred by the need for increased cooling by advanced computer systems. Liquid cooling is the currently accepted solution for rapid heat removal due to the superior thermal performance from liquid cooling. At room temperature, the heat transfer coefficient of air is only 0.024 W/mK, while a coolant, such as water, has a heat transfer coefficient of 0.58 W/mK, which is 24 times than that of air. Other coolants, which may be oil based dielectric fluid has a lower heat transfer coefficient but is still much more efficient than air. Thus, liquid cooling is more effective in transporting heat away from a heat source to a radiator, and allows heat removal from critical parts without noise pollution required by fan systems.

One technique that is currently employed is to provide a liquid tank holding coolant. Server blades are immersed in the coolant held by the tank. In this manner, heat generated by the server blades is transferred to the coolant and efficiently transferred away. In traditional immersion cooling, a heat-generating electrical component such as a server, a storage unit, or a switch, is held by a liquid tank for cooling during operation. FIG. 1A shows a prior art computer server system 10. The system 10 includes a series of liquid tanks 12. Each of the tanks 12 hold coolant. Electronic components 14 such as server blades are suspended in the tanks 12 and immersed in the coolant. Servicing infrastructure for the tanks 12 includes a robot/arm 20 that may be remotely controlled to pick up or insert the electronic components 14 into the tank 12. The tank 12 may be integrated in with facility infrastructure 30 that integrates pump/heat exchanger/piping functions with the data center building. The components of the infrastructure 30 serve as a heat transfer device between the immersion fluid in the tank 12 and a facility water-based cooling system as shown in FIG. 1B.

The infrastructure 30 includes a heat exchanger and hoses 32 that collect and supply coolant to the liquid tanks 12. The infrastructure 30 also includes the actuators and other mechanical components for the robot/arm 20 for manipulating the electronic components 14. However, the immersion cooling system 10 requires a large footprint for both the liquid tanks 12, the heat exchange infrastructure 30, as well as the machinery for supporting the robot/arm 20. When a component requires service or replacement, the robot/arm 20 picks up the component 14 from the tank 12. Further, the robot/arm 20 must be stopped to suspend the component 14 above the liquid tank 12 as shown in FIG. 1B. This is done for cooling liquid to flow out of the chassis of the component 14. The component 14 is suspended until the coolant flows out of the chassis. After the coolant flows out, the robot/arm 20 can then move the component 14, where it can be serviced. Current immersion coolant systems thus require space in a data center as well as requires time for servicing the components.

Thus, there is a need for a compact and modular rack sized heat exchanger that supports different coolant systems. There is a further need for an efficient liquid-to-liquid heat exchanger that minimizes support infrastructure. There is a further need for a heat exchanger unit that can support different liquid cooling mechanisms.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, an example rack unit for circulating coolant to equipment racks is disclosed. The rack unit has a cold coolant manifold for supplying coolant to an electronic component. The rack unit has a pump fluidly coupled to the cold coolant manifold for circulating the coolant. The rack unit has a hot coolant manifold for collecting hot coolant from the electronic component. The rack unit has a liquid-to-liquid heat exchanger fluidly coupled to the cold coolant manifold and the hot coolant manifold to form a first coolant loop. The first coolant loop transfers heat to a second coolant loop formed in part by the liquid-to-liquid heat exchanger.

A further implementation of the example rack unit includes a second redundant pump circulating the coolant. Either the first or second pump is removable from the rack unit while the other pump remains operating. Another implementation is where the liquid-to-liquid heat exchanger includes a cold coolant connector coupled to the cold coolant manifold, a hot coolant connector coupled to the hot coolant manifold, a supply connector, and a collection connector. The second coolant loop includes an external cooling system supplying coolant to the supply connector and collecting coolant from the supply connector. Another implementation is where the electronic component is mounted on an equipment rack. The equipment rack includes an internal supply manifold fluidly coupled to the cold coolant manifold and an internal collection manifold fluidly coupled to the hot coolant manifold. Another implementation is where a footprint of the equipment rack is the same as a footprint of the rack unit. Another implementation is where the electronic component has a liquid sealed chassis having heat-generating elements immersed in coolant, a supply connector fluidly connected to the internal supply manifold, and a collection connector fluidly connected to the internal collection manifold. Another implementation is where the electronic component has a chassis having a heat-generating element, a supply connector fluidly connected to the internal supply manifold, a collection connector fluidly connected to the internal collection manifold, and a cold plate supplied by the coolant from the supply connector for cooling the heat-generating element. Another implementation is where the electronic component is one of an application server, a storage server, a storage device, or a network switch. Another implementation is where the example rack unit includes a cabinet having a door holding the first pump and the liquid-to-liquid heat exchanger.

According to certain aspects of the present disclosure, an example equipment system is disclosed. The equipment system includes an electronic heat-generating component having a hot coolant connector and a cold coolant connector. An equipment rack holds the electronic component. The equipment rack has an internal supply manifold coupled to the cold coolant connector and an internal collection manifold coupled to the hot coolant connector. A rack mounted coolant unit includes a cold coolant manifold for supplying coolant to the internal supply manifold. The rack mounted coolant unit includes a first pump fluidly coupled to the cold coolant manifold for circulating the coolant. A hot coolant manifold collects hot coolant from the internal collection manifold. A liquid-to-liquid heat exchanger is fluidly coupled to the cold coolant manifold and the hot coolant manifold to form a first coolant loop. The first coolant loop transfers heat to a second coolant loop formed in part by the liquid-to-liquid heat exchanger.

A further implementation of the example equipment system is where the rack mounted coolant unit includes a second redundant pump circulating the coolant. Either the first or second pump is removable from the rack unit while the other pump remains operating. Another implementation is where the liquid-to-liquid heat exchanger includes a cold coolant connector coupled to the cold coolant manifold, a hot coolant connector coupled to the hot coolant manifold, a supply connector, and a collection connector. The second coolant loop includes an external cooling system supplying coolant to the supply connector and collecting coolant from the supply connector. Another implementation is where the example equipment system includes another electronic heat-generating component is mounted on the equipment rack. Another implementation is where a footprint of the equipment rack is the same as a footprint of the rack unit. Another implementation is where the electronic component has a liquid sealed chassis having heat-generating elements immersed in coolant, a supply connector fluidly connected to the internal supply manifold, and a collection connector fluidly connected to the internal collection manifold. Another implementation is where the electronic component has chassis having a heat-generating element, a supply connector fluidly connected to the internal supply manifold, a collection connector fluidly connected to the internal collection manifold, and a cold plate supplied by the coolant from the supply connector for cooling the heat-generating element. Another implementation is where the electronic component is one of an application server, a storage server, a storage device, or a network switch. Another implementation is where the rack mounted coolant unit includes a cabinet having a door holding the first pump and the liquid-to-liquid heat exchanger. Another implementation is where the example equipment system includes another equipment rack having an internal supply manifold coupled to the cold coolant connector and an internal collection manifold coupled to the hot coolant connector.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is a perspective view of a prior art immersion cooling system for a set of servers in a data center;

FIG. 1B is a perspective view of the removal of a server from a coolant tank in the prior art immersion cooling system in FIG. 1A;

FIG. 2 is a diagram of a data center having a set of racks for supporting computer components and an example rack based liquid-to-liquid heat exchange unit;

FIG. 3 is a cutaway diagram of the coolant flow for the example set of racks and liquid-to-liquid heat exchange unit in FIG. 2;

FIG. 4 is a perspective diagram of the elements that form the coolant closed loops that incorporate the example rack based liquid-to-liquid heat exchange unit;

FIG. 5A is a side view of the example rack-based liquid-to-liquid heat exchange unit in FIG. 2;

FIG. 5B is an opposite side perspective view of the rack-based liquid-to-liquid heat exchange unit in FIG. 2;

FIG. 6 is a perspective view of an equipment rack that may be supplied with coolant from the example rack based liquid-to-liquid heat exchange unit in FIG. 2;

FIG. 7 is a perspective view of a first type of rack mounted electronic component that uses immersion type cooling; and

FIG. 8 is a perspective view of a second type of rack mounted electronic component that has internal cold plates that require coolant supplied by the example rack based liquid-to-liquid heat exchange unit.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

The present disclosure relates to an industrial rack or cabinet unit that holds a liquid-to-liquid based cooling system to provide coolant fluid to other racks in a data center. The heat exchanger rack or cabinet unit may support liquid immersion cooling of electronic components on other racks or other types of racks. Electronic components may include servers, storage devices, and network switches that require liquid cooling. Such components typically have a system chassis (server/storage/switch) with various height, width or depth units slotted horizontally onto the rack. The heat exchanger rack circulates coolant to the racks that in turn circulate coolant to the components mounted on the rack. The rack footprint of the heat exchanger unit makes it efficient to support liquid cooling as the heat exchanger can fit into spaces designed for conventional racks to provide liquid cooling for other racks.

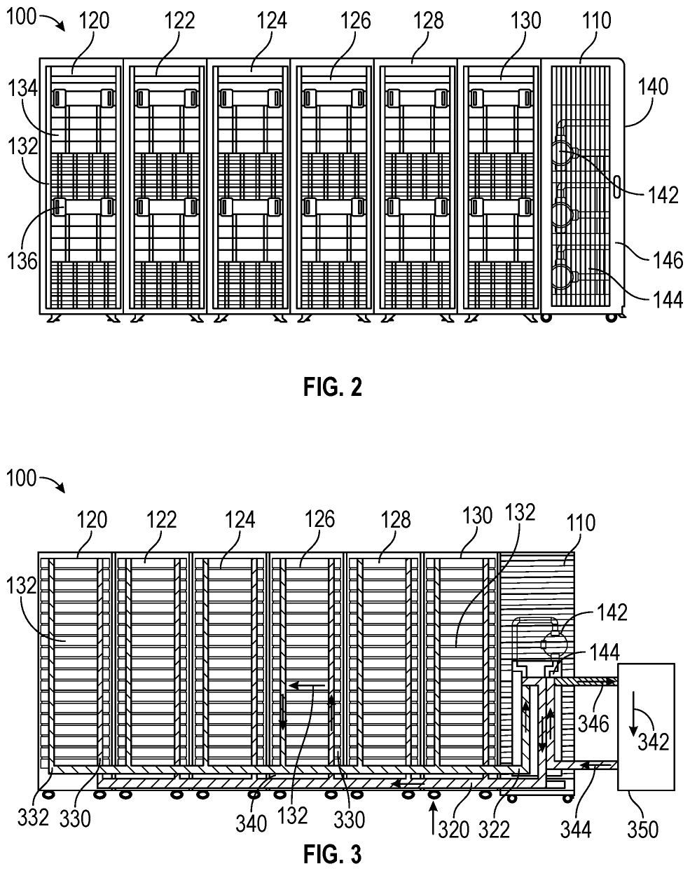

FIG. 2 shows a set of component racks in a data center 100. The data center 100 may include multiple sets of racks that each hold multiple computing components. Immersion cooling for different heat-generating components on racks is provided by a dedicated heat exchanger rack 110. The data center 100 has a series of racks 120, 122, 124, 126, 128, and 130 that each have shelves that hold electronic components. In this example, the space between each of the shelves is a standard unit, U. One or more shelves may be removed to accommodate components with a greater height than 1U. For example, the rack 120 includes 1U height components 132 such as a server, 2U height components 134 such as a switch, and 4U height components 136 such as a storage device. The components 132, 134, and 136 each have liquid tight chassis that holds coolant that immerses heat-generating units such as processors, storage devices, power supplies and the like that are contained in the chassis.

The example dedicated heat exchanger rack 110 has an enclosed cabinet 140 that holds a pump unit 142 that circulates coolant fluid to the different components in each of the other racks 120, 122, 124, 126, 128, and 130. The heat exchanger rack 110 has a liquid-to-liquid heat exchanger 144 that performs heat transfer between returned coolant from the other rack and the data center facility water cooling infrastructure that provides cooling for the entire data center. The pump unit 142 and the liquid-to-liquid heat exchanger 144 in the cabinet 140 may be accessed via a door 146. The cabinet 140 also includes support components such as power supplies, controllers, sensors and the like.

FIG. 3 is a coolant flow diagram of the heat exchanger rack 110 and the racks 120, 122, 124, 126, 128, and 130 of the data center 100. The pump unit 142 of the heat exchanger rack circulates coolant to each rack 120, 122, 124, 126, 128, and 130 via an outside supply pipe 320. Each of the components on the racks are sealed to immerse internal elements in the coolant. In this example, the immersion coolant is a dielectric fluid which typically is oil based. Coolant from components on each rack 120, 122, 124, 126, 128, and 130 is returned to the heat exchanger rack 110 via a return pipe 322. Each rack 120, 122, 124, 126, 128, and 130 has an internal supply manifold 330 that can distribute immersion fluid to the chassis of each of the electronic heat-generating components. Each of the racks 120, 122, 124, 126, 128, and 130 also has a return collection manifold 332 that collects heated coolant from the electronic heat-generating components for return to the heat exchanger rack 110. The liquid-to-liquid heat exchanger 144 removes heat from the returned coolant. Thus, the heat exchanger 144 forms a closed first liquid coolant loop 340 with the racks 120, 122, 124, 126, 128, and 130. The pump unit 142 circulates coolant through the first liquid coolant loop 340.

A second liquid coolant heat removal loop 342 includes the heat exchanger 144 and support infrastructure 350 of the data center. The second liquid coolant loop 342 removes heat from the coolant circulating in the heat exchanger 144 from the racks 120, 122, 124, 126, 128, and 130. Thus, the liquid-to-liquid heat exchanger 144 internally transfers heat from the first liquid coolant loop 340 to the second coolant loop 342. In this example, the coolant in the second coolant loop 342 is water. The liquid coolant heat removal loop 342 includes a cold water supply pipe 344 that supplies cold water to the heat exchanger 144. Heat is transferred by the returned coolant from the racks 120, 122, 124, 126, 128, and 130 through the heat exchanger 144 to the second liquid coolant loop 342. The heated coolant is returned to the support infrastructure 350 through a hot water outlet pipe 346. The support infrastructure 350 cools the heated coolant from the heat exchanger 144 and returns the cooled coolant to the cold water supply pipe 344.

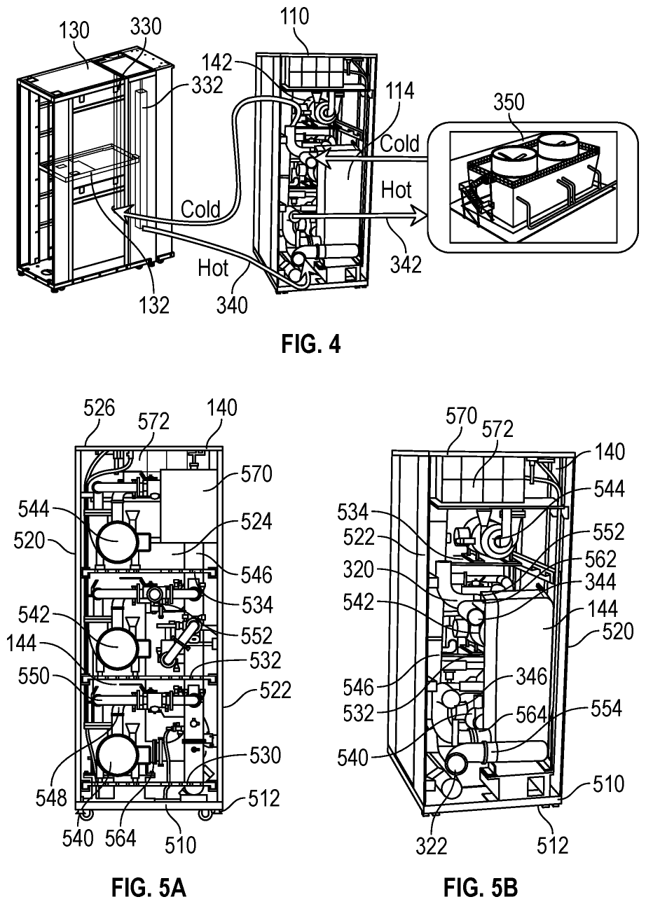

FIG. 4 is a diagram of the key elements that are part of the coolant loops 340 and 342 of the data center 100 in FIG. 3. As explained above, the first liquid coolant loop 340 is a closed loop that circulates coolant between components on racks such as the rack 130 and the dedicated heat exchanger rack 110. The second coolant loop 342 circulates coolant in a closed loop between the heat exchanger rack 110 and the support infrastructure 350 for the data center 100. Heat is exchanged between the loops 340 and 342 in the heat exchanger 144 via a liquid-to-liquid heat transfer process. The support infrastructure 350 may include an external cooling system with fans to transfer heat from the circulated coolant to the external environment of the data center.

FIG. 5A is a side cutaway view of the heat exchanger rack 110. FIG. 5B is an opposite side cutaway view of the heat exchanger rack 110. The heat exchanger rack 110 has a rectangular bottom frame 510. The bottom frame 510 includes a set of wheels 512 attached to the bottom of the frame 510. The wheels 512 allow the heat exchanger rack 110 to be moved to desired locations in a data center to provide cooling support for other racks of electronic components. The footprint defined by the bottom frame 510 is identical or substantially identical to that of the other racks 120, 122, 124, 126, 128, and 130 in FIG. 2. Thus, the heat exchanger rack 110 may thus be located next to one or more racks to provide cooling with additional infrastructure other than a power and water supply. The floor area required for the heat exchanger rack 110 is uniform with that for equipment racks, thus providing efficient placement in a data center. Side members of the bottom frame 510 support two side walls 520 and 522, and a back wall 524 that form the cabinet 140. A top frame 526 joins the walls 520, 522, and 524 to enclose the cabinet 140. The door 146 in FIG. 3 (not shown for clarity) is attached to the wall 520.

Three front shelves 530, 532, and 534 are supported by the side walls 520 and 522. The shelves 530, 532 and 534 each hold a respective redundant pump 540, 542, and 544. Each of the pumps 540, 542, and 544 are fluidly coupled to a supply manifold 546. Each of the pumps 540, 542, 544 circulate coolant through the supply manifold 546. In this example, each of the pumps 540, 542, 544 have an inlet 548 receiving coolant from the supply manifold 546 and push the coolant via a pump motor to an outlet 550 that is fluidly coupled to the supply manifold 546. The supply manifold 546 supplies the coolant to the electronic components on the racks such as the rack 120. In this example, each of the pumps 540, 542, and 544 are redundant units and thus an individual pump may be replaced while the remaining pumps remain operating, thus reducing down time of the heat exchanger rack 110. Although three pumps are used in this example, any number of pumps may be used to circulate the coolant in the heat exchanger rack 110.

Each of the pumps 540, 542, and 544 may be connected to the supply manifold 546 via quick connect valves. Such valves may be shut off for a single pump, and the pump may then be removed without disrupting the operation of the other pumps. A pump may be replaced by attaching the pump to the shelf, providing power to the motor, connecting the quick connect values to the inlet 548 and the outlet 550, and opening the valves to allow coolant flow to the newly installed pump.

A cold coolant connection 552 of the heat exchanger 144 supplies cold coolant to the supply pipe 320 for supply to the internal manifolds of the equipment racks. A hot coolant connection 554 of the heat exchanger 144 receives heated coolant from the electronic components of the equipment racks via the hot coolant return pipe 322. The heat exchanger 144 has a series of interlocking coils that allow heat transfer from the coolant in the first liquid coolant loop 340 to the water coolant in the second liquid coolant loop 342 in FIG. 3. The coils of the first liquid coolant loop 340 are fluidly isolated from the coils of the second liquid coolant loop 342, but heat transfer occurs between the two sets of coils. The heat exchanger 144 has a cold water connection 562 that is coupled to cold water supplied by the cold water supply pipe 344. The heat exchanger 144 also has a hot water connection 564 that is coupled to the hot water outlet pipe 346.

The heat exchanger rack 110 also includes a control box that holds a controller for the pumps 540, 542, and 544. The controller regulates the pump motor speed of the pumps 540, 542, and 544 to keep the coolant flow at a consistent level. The controller may also increase or decrease the pump speed of the pumps 540, 542, and 544 according to an operating routine to increase or decrease the rate of coolant flow to match the cooling needs of components on the racks serviced by the heat exchanger rack 110. The controller may also monitor coolant flow and temperature through sensors and control other components of the heat exchanger rack 110. A reservoir tank 572 holds additional coolant.

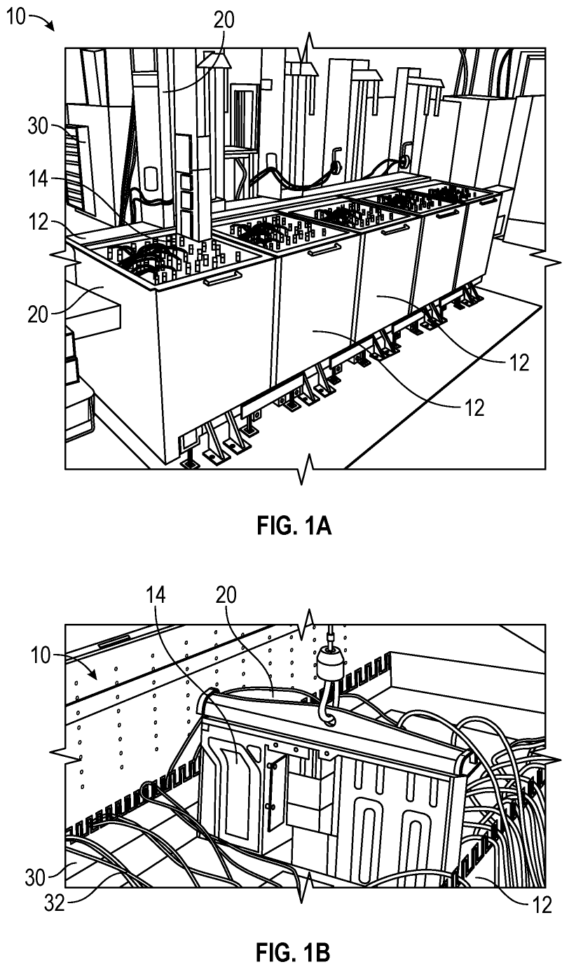

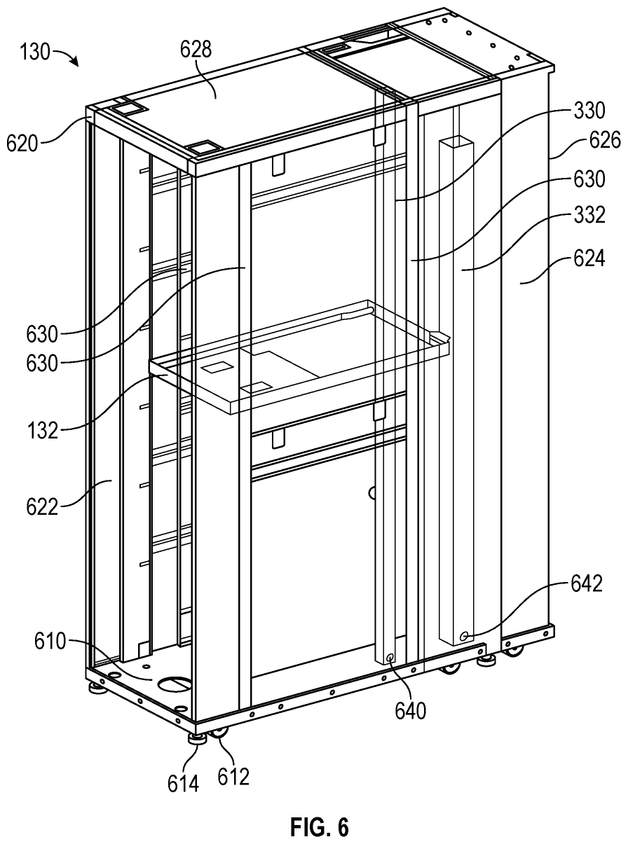

FIG. 6 is a perspective view of the rack 130 in FIG. 1 with one example component 132 installed. The rack 130 may hold multiple components as shown in FIG. 1, but only one component 132 is shown for ease of illustration. The rack 130 includes a rectangular bottom frame 610. The bottom frame 610 includes a set of wheels 612 attached to the bottom of the frame 610. The wheels 612 allow the rack 130 to be moved to desired locations in a data center. A series of extendable supports 614 allow the rack 130 to be fixed in place when extended to contact a floor. A cabinet 620 is formed by two side walls 622 and 624 and a back wall 626. A top panel 628 encloses the walls 622, 624 and 626. The side walls 622 and 624 and the bottom frame 610 support vertical supports 630. The top panel 628 holds lateral bracing members 632 and 634, which connect the tops of the vertical supports 630 to the vertical supports 630 of the opposite side of the rack 130. Each of the vertical supports 630 may include holes to allow pins to be inserted. The pins may support shelves that may be installed between (i) the supports 630 and (ii) the corresponding supports 630 on the other side of the rack 130.

The components such as the electronic component 132 may be pushed into the rack 120 from the open side between the walls 622 and 624 until they contact a stop mechanism. The individual component 132 may also be pulled out of the rack 130 from the front of the rack 130 between the supports 630, for replacement or service. The rack 130 includes infrastructure to support power cables and data cables that may be attached to the electronic component 132. Simple service may be performed when the component 132 is installed in the rack 130 because the front end is open.

Each of the shelves attached to the supports 630 may hold one or more of the heat-generating electronic components. The shelves may be arranged to have different U heights between the shelves such as 1U, 2U and 4U heights. It is understood that any number of shelves and corresponding heat-generating components may be installed in the rack 130. In this example, the placement of the components in the rack 130 is in a horizontal orientation. However, with additional internal structures connected to the supports 630, the heat-generating component could be in a vertical orientation.

The rack 130 supports the supply manifold 330 and the collection manifold 332, each of which extends over the height of the rack 130 at the rear of the rack 130 between the supports 630. The supply manifold 330 is fluidly connected to the heat exchanger rack 110 via a coupler 640. The collection manifold 332 is fluidly connected to the heat exchanger rack 110 via a coupler 642. The supply manifold 330 includes an opposite coupler that may be coupled to the next rack 128 in FIG. 2 to allow flow of the cold coolant to the next rack such as the rack 128. The collection manifold 332 includes an opposite coupler that may be coupled to the next rack such as the rack 128 in FIG. 2 to allow collection of hot coolant from the internal collection manifold of the rack 128.

Each of the manifolds 330 and 332 can allow coolant to circulate along the respective length of the manifold through the rack 120. The manifolds 330 and 332 have respective fluid couplers spaced at periodic intervals that allow fluid communication of coolant to one of the components such as the component 132. Once the couplers are connected to allow fluid communication to the component 132 from the manifolds 330 and 332, the component 132 may be liquid cooled via immersion coolant supplied by the heat exchanger rack 110. The couplers on the supply manifold 330 and the collection manifold 332 may be quick-disconnect connectors that facilitate quick, easy, and toolless connection and disconnection of the manifold to the electronic heat-generating component.

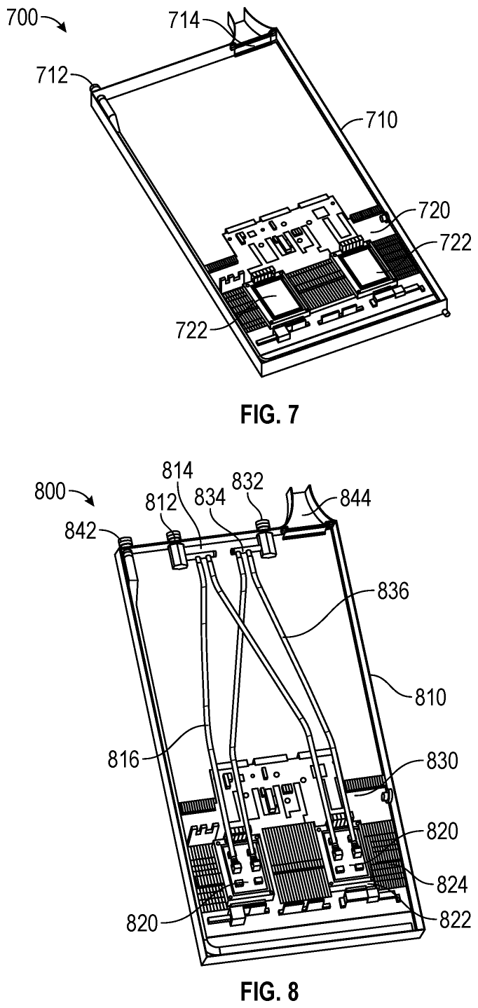

FIG. 7 shows an example electronic heat-generating component 700 that has a fully sealed chassis 710 that encloses the electronics and other parts of the electronic component 700. In this example, the cover of the chassis 710 is not shown for illustration purposes. In this example, the rear of the chassis 710 of the component 700 includes an inlet connector 712, which may be connected to one of the fluid couplers of the supply manifold 330 in the rack 130 in FIG. 6. The rear of the chassis 710 also includes an outlet connector 714, which may be connected to one of the fluid couplers of the collection manifold 332.

The fully sealed chassis 710 encloses electronic components, power supplies, circuit boards, device cards, processors, memory devices, and other elements. The chassis 710 holds a main circuit board 720. The main circuit board 720 in this example includes processors 722 and other components that generate heat. The chassis 710 holds coolant that immerses the enclosed electronic components, power supplies, circuit boards, device cards, processors, memory devices, and other elements. In this example, the immersion coolant is a dielectric fluid which typically is oil based. The coolant transfers heat generated by the elements to flowing coolant exiting the outlet connector 714. Fresh cold coolant is supplied through the inlet connector 712. The coolant is thus fully sealed in the chassis 710 and can only enter or exit the chassis 710 via the inlet connector 712 or the outlet connector 714.

In this example, the individual heat-generating component 700 may be inserted on a shelf from the front of the rack 130. Once in place, the inlet connector 712 is fluidly connected with one of the couplers of the supply manifold 330, and the outlet connector 714 is fluidly connected with one of the couplers of the collection manifold 332. The component 700 may be connected to a power supply for power and other cables for carrying data signals. Any heat generating component such as a server, a storage device, a network switch, a router, and the like may be installed and cooled by the coolant supplied by the supply manifold 330.

FIG. 8 shows another example of an electronic heat generating component 800 that may be installed on the rack 130. For example, the component 800 may be an application server having processing devices such as CPUs and GPUs. The electronic component 800 has a liquid sealed chassis 810 that encloses the electronics of the electronic component 800 and holds coolant. In this example, the rear of the chassis 810 of the component 800 includes an inlet connector 812, which may be connected to another supply manifold for a different type of coolant such as water. The inlet connector 812 provides coolant fluid to an internal manifold 814. The internal manifold 814 supplies coolant to different hoses 816. In this example, the hoses 816 supply coolant to different cold plates 820. The component 800 has a main circuit board 830 that mounts heat generating elements such as CPUs or GPUs 822. The cold plates 820 are installed in thermal contact with the CPUs and GPUs 822, as well as adjacent memory devices such as DIMMs 824. Although there are two CPUs and two corresponding cold plates, there may be any number of cold plates and processors. A single cold plate may provide cooling for multiple processors or other components.

The coolant circulates through the cold plates 820 and heat from the CPUs 822 is transferred to the coolant. The rear of the chassis 810 also includes an outlet connector 832, which may be connected to a collection manifold. The outlet connector 832 allows fluid communication to a collection manifold 834. The internal collection manifold 834 collects heated coolant through hoses 836. The opposite end of the hoses 836 are coupled to the cold plates 820 to collect the heated coolant. The collection manifold may be connected to a second cooling system that cools the collected coolant and supplies cold coolant to the inlet connector 812.

In this example, the rear of the chassis 810 of the component 800 also includes an inlet connector 842, which may be connected to one of the fluid couplers of the supply manifold 330 in the rack 130 in FIG. 6. The rear of the chassis 810 also includes an outlet connector 844, which may be connected to one of the fluid couplers of the collection manifold 332. The coolant thus may fill the interior of the fully sealed chassis 810 from the inlet connector 842 to immerse the enclosed electronic components, power supplies, circuit boards, device cards, processors, memory devices, and other elements. The coolant transfers heat generated by the elements to flowing coolant exiting the outlet connector 844. Fresh cold coolant is supplied through the inlet connector 842.

In this example, the individual heat-generating component 800 may be inserted on a shelf from the front of the rack 130. Once in place, the inlet connector 842 is fluidly connected with a coupler of the supply manifold 330, and the outlet connector 844 are fluidly connected with the coupler of the collection manifold 332. The rack unit 110 may thus provide immersion coolant to the component 800. The inlet connector 812 and the outlet connector 832 may be connected to another coolant circulation system to provide coolant to the cold plates. The component 800 may be connected to a power supply for power and other cables for carrying data signals. Any heat generating component such as a server, a storage device, a network switch, a router, and the like may be installed and cooled by the coolant supplied by the supply manifold 330.

An alternative to the components 700 and 800 that may be supported by the heat exchanger rack unit 110 may be a component having an unsealed chassis that routes the coolant through internal hoses and manifolds to cold plates or similar cooling devices that may be located in thermal contact with heat-generating elements such as processors.

The advantages of the example industrial rack or cabinet based heat exchanger is the ability to supply and circulate coolant to a row of component racks. The example rack based exchanger includes a set of pumps that provide pressure to move the heated coolant to the heat exchanger to heat exchange as a cycle with an external coolant system.

The example rack based heat exchanger can provide better serviceability because it eliminates the need of additional robot/arm to pick up sever/storage/switch. In addition, the rack footprint is much smaller than conventional immersion cooling system with a big tank and supporting infrastructure. The example rack unit has the rack layout as racks within a current data center thus providing case of location of the unit. The present rack unit also works with both components allowing immersion cooling and those with components that use cold plates for liquid cooling.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A rack unit for circulating coolant, the rack unit comprising:
a cold coolant manifold for supplying coolant to an electronic component;
a first pump fluidly coupled to the cold coolant manifold for circulating the coolant;
a hot coolant manifold for collecting hot coolant from the electronic component;
a liquid-to-liquid heat exchanger fluidly coupled to the cold coolant manifold and the hot coolant manifold to form a first coolant loop, wherein the first coolant loop transfers heat to a second coolant loop formed in part by the liquid-to-liquid heat exchanger.

2. The rack unit of claim 1, further comprising a second pump circulating the coolant, wherein either the first pump or the second pump is removable from the rack unit while the other pump remains operating, the second pump being redundant with the first pump.

3. The rack unit of claim 1, wherein the liquid-to-liquid heat exchanger includes a cold coolant connector coupled to the cold coolant manifold, a hot coolant connector coupled to the hot coolant manifold, a supply connector, and a collection connector, wherein the second coolant loop includes an external cooling system supplying coolant to the supply connector and collecting coolant from the supply connector.

4. The rack unit of claim 1, wherein the electronic component is mounted on an equipment rack, wherein the equipment rack includes an internal supply manifold fluidly coupled to the cold coolant manifold and an internal collection manifold fluidly coupled to the hot coolant manifold.

5. The rack unit of claim 4, wherein a footprint of the equipment rack is the same as a footprint of the rack unit.

6. The rack unit of claim 4, wherein the electronic component has a liquid sealed chassis having heat-generating elements immersed in coolant, a supply connector fluidly connected to the internal supply manifold, and a collection connector fluidly connected to the internal collection manifold.

7. The rack unit of claim 4, wherein the electronic component has a chassis having a heat-generating element, a supply connector fluidly connected to the internal supply manifold, a collection connector fluidly connected to the internal collection manifold, and a cold plate supplied by the coolant from the supply connector for cooling the heat-generating element.

8. The rack unit of claim 1, wherein the electronic component is one of an application server, a storage server, a storage device, or a network switch.

9. The rack unit of claim 1, further comprising a cabinet having a door holding the first pump and the liquid-to-liquid heat exchanger.

10. An equipment system comprising:
an electronic heat-generating component having a hot coolant connector and a cold coolant connector;
an equipment rack holding the electronic heat-generating component, the equipment rack having an internal supply manifold coupled to the cold coolant connector and an internal collection manifold coupled to the hot coolant connector;
a rack mounted coolant unit including:
a cold coolant manifold for supplying coolant to the internal supply manifold;
a first pump fluidly coupled to the cold coolant manifold for circulating the coolant;
a hot coolant manifold for collecting hot coolant from the internal collection manifold;
a liquid-to-liquid heat exchanger fluidly coupled to the cold coolant manifold and the hot coolant manifold to form a first coolant loop, wherein the first coolant loop transfers heat to a second coolant loop formed in part by the liquid-to-liquid heat exchanger.

11. The equipment system of claim 10, wherein the rack mounted coolant unit includes a second pump circulating the coolant, wherein either the first pump or the second pump is removable from the rack unit while the other pump remains operating, the second pump being redundant with the first pump.

12. The equipment system of claim 10, wherein the liquid-to-liquid heat exchanger includes a cold coolant connector coupled to the cold coolant manifold, a hot coolant connector coupled to the hot coolant manifold, a supply connector, and a collection connector, wherein the second coolant loop includes an external cooling system supplying coolant to the supply connector and collecting coolant from the supply connector.

13. The equipment system of claim 10, further comprising another electronic heat-generating component is mounted on the equipment rack.

14. The equipment system of claim 10, wherein a footprint of the equipment rack is the same as a footprint of the rack unit.

15. The equipment system of claim 10, wherein the electronic heat-generating component has a liquid sealed chassis having heat-generating elements immersed in coolant, a supply connector fluidly connected to the internal supply manifold, and a collection connector fluidly connected to the internal collection manifold.

16. The equipment system of claim 10, wherein the electronic heat-generating component has a chassis having a heat-generating element, a supply connector fluidly connected to the internal supply manifold, a collection connector fluidly connected to the internal collection manifold, and a cold plate supplied by the coolant from the supply connector for cooling the heat-generating element.

17. The equipment system of claim 10, wherein the electronic component is one of an application server, a storage server, a storage device, or a network switch.

18. The equipment system of claim 10, wherein the rack mounted coolant unit includes a cabinet having a door holding the first pump and the liquid-to-liquid heat exchanger.

19. The equipment system of claim 10, further comprising another equipment rack having an internal supply manifold coupled to the cold coolant connector and an internal collection manifold coupled to the hot coolant connector.
